(19) United States
(12) Patent Application Publication
(10) Pub. No.: US 2026/0239750 A1
(43) Pub. Date: Aug. 13, 2026

(54) SENSORS INCLUDING PHOTODETECTORS WITH INTEGRATED TEMPERATURE SENSORS

(71) Applicant: GlobalFoundries U.S. Inc., Malta, NY (US)

(72) Inventors: CHARLES PIKE, Burlington, VT (US); ANDREAS DANIEL STRICKER, Essex, VT (US); ABDELSALAM ABOKETAF, Clifton Park, NY (US); HANYI DING, Colchester, VT (US)

(21) Appl. No.: 19/049,004

(22) Filed: Feb. 10, 2025

(51) Int. Cl. H10F 39/10; G01K 1/14; H10F 71/00

(52) U.S. Cl. CPC H10F 39/103; G01K 1/14; H10F 71/00; G01K 2217/00

(57) ABSTRACT

The embodiments herein relate to sensors including photodetectors with integrated temperature sensors. The sensor includes a substrate, a photodetector, and a temperature sensor. The substrate includes a device layer over a base substrate. The photodetector and the temperature sensor are in the device layer, and the temperature sensor is adjacent to the photodetector.

### TECHNICAL FIELD

The present disclosure relates generally to semiconductor devices, and more particularly to sensors including photodetectors with integrated temperature sensors and methods of forming the same.

### BACKGROUND

Photodetectors are sensors that sense illumination and convert light (photons) into electrical charge. Measurements from photodetectors may be qualitative, i.e., the presence or absence of illumination, or quantitative, i.e., a measurement of the intensity of illumination received. Responsivity is an example of a quantitative measurement of a photodetector and is a measure of the electrical output per optical input.

Photodetectors are widely used in various applications such as optical communication systems, medical imaging, and environmental monitoring. Accordingly, the calibration of photodetectors is crucial to ensure accurate and reliable measurements. Therefore, continuous advancements in photodetector technology are necessary to meet the growing demands of emerging applications. In this disclosure, sensors including photodetectors with integrated temperature sensors and methods of forming the same are presented.

### SUMMARY

To achieve the foregoing and other aspects of the present disclosure, sensors including photodetectors with integrated temperature sensors and methods of forming the same are presented.

According to an aspect of the present disclosure, a sensor for sensing illumination is provided. The sensor includes a substrate, a photodetector, and a temperature sensor. The substrate includes a device layer over a substrate. The photodetector and the temperature sensor are in the device layer, and the temperature sensor is adjacent to the photodetector.

According to another aspect of the present disclosure, a method of forming a sensor for sensing illumination is provided. The method includes forming a photodetector in a device layer of a substrate, the substrate includes a base substrate under the device layer, and forming a temperature sensor in the device layer adjacent to the photodetector.

### BRIEF DESCRIPTION OF THE DRAWINGS

The embodiments of the present disclosure will be better understood from a reading of the following detailed description, taken in conjunction with the accompanying drawings.

FIG. 1A is a top-down view of a sensor and FIG. 1B is a cross-sectional view of the sensor in FIG. 1A, taken generally along line 1B-1B thereof, according to an embodiment of the disclosure.

FIG. 2A is a top-down view of a sensor and FIG. 2B is a cross-sectional view of the sensor taken generally along line 2B-2B in FIG. 2A, according to an embodiment of the disclosure.

FIG. 3A is a top-down view of a sensor and FIG. 3B is a cross-sectional view of the sensor taken generally along line 3B-3B in FIG. 3A, according to an embodiment of the disclosure.

FIG. 4A is a top-down view of a sensor and FIG. 4B is a cross-sectional view of the sensor taken generally along line 4B-4B in FIG. 4A, according to an embodiment of the disclosure.

FIG. 5 is a flow chart illustrating a method of forming a sensor, according to an embodiment of the disclosure.

FIG. 6 is a flow diagram illustrating the flow of power through a sensor, according to an embodiment of the disclosure.

For simplicity and clarity of illustration, the drawings illustrate the general manner of construction, and certain descriptions and details of features and techniques may be omitted to avoid unnecessarily obscuring the discussion of the described embodiments of the device.

Additionally, elements in the drawings are not necessarily drawn to scale. For example, the dimensions of some of the elements in the drawings may be exaggerated relative to other elements to help improve understanding of embodiments of the device. The same reference numerals in different drawings denote the same elements, while similar reference numerals may, but do not necessarily, denote similar elements.

### DETAILED DESCRIPTION

The present disclosure relates to semiconductor devices, and more particularly to sensors including photodetectors with integrated temperature sensors and methods of forming the same. The photodetector may be calibrated by the temperature sensor using the Electrical Substitution Method (ESM). Various embodiments of the present disclosure are now described in detail with accompanying drawings. It is noted that like and corresponding elements are referred to by the use of the same reference numerals. The embodiments disclosed herein are exemplary, and not intended to be exhaustive or limiting to the disclosure.

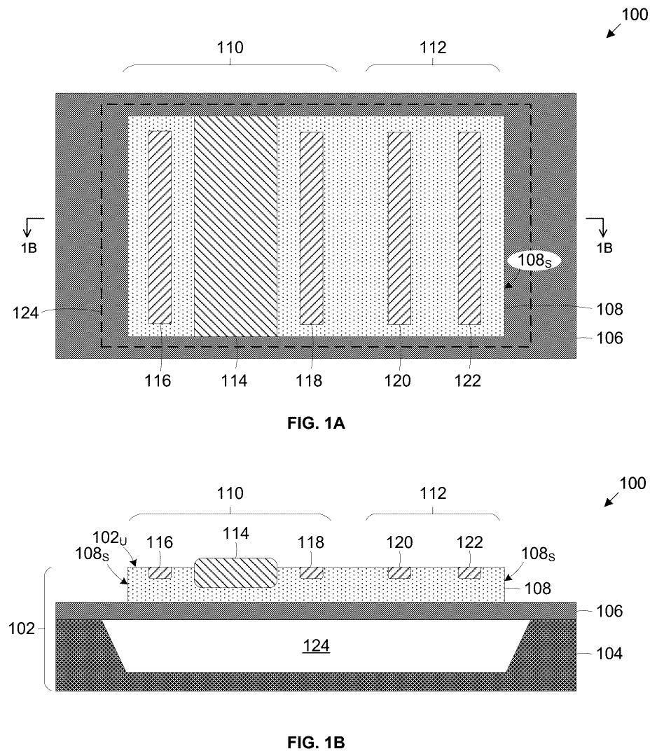

FIG. 1A is a top-down view of a sensor 100 and FIG. 1B is a cross-sectional view of the sensor 100 taken generally along line 1B-1B in FIG. 1A, according to an embodiment of the disclosure. The sensor 100 may include a substrate 102, such as a semiconductor-on-insulator (SOI) substrate having a base substrate 104, a buried insulator layer 106 over the base substrate 104, and a device layer 108 over the buried insulator layer 106. The device layer 108 may be a patterned portion of a semiconductor layer, and may also be commonly referred to as an active layer. The substrate 102 may have an upper substrate surface 102_{U} and the upper substrate surface 102_{U} may be analogous to an uppermost surface of the device layer 108. Alternatively, the substrate 102 may be a bulk semiconductor substrate, even though this embodiment is not illustrated in the accompanying drawings.

The base substrate 104 and the device layer 108 may include a semiconductor material, such as silicon, silicon germanium, silicon carbide, or other II-VI or III-V semiconductor compounds, though not necessarily the same semiconductor material. The base substrate 104 and the device layer 108 may be doped or undoped. The buried insulator layer 106 may serve to electrically isolate the device layer 108 from the base substrate 104. The buried insulator layer 106 may include an electrically insulating material, such as silicon dioxide or aluminum oxide, and may also be commonly referred to as a buried oxide (BOX) layer.

The sensor 100 may include a photodetector 110 and a temperature sensor 112 laterally adjacent to the photodetector 110. The photodetector 110 and the temperature sensor 112 may be arranged in and over the device layer 108. Specifically, the photodetector 110 and the temperature sensor 112 may be arranged in and/or over the same slab of device layer 108, i.e., the sensor 100 may be a monolithic structure. The device layer 108 may be thermally isolated from surrounding features such that the photodetector 110 may be thermally coupled to the temperature sensor 112 through the device layer 108. For example, the device layer 108 may be thermally isolated by thermally insulating materials, such as dielectrics including silicon dioxide. The device layer 108 may be collectively surrounded by the buried insulating layer 106 from below and by the dielectrics (not shown) from laterally and above. In an embodiment of the disclosure, the photodetector 110 is immediately laterally adjacent to the temperature sensor 112. In another embodiment of the disclosure, intervening structures are absent in the device layer 108 between the photodetector 110 and the temperature sensor 112.

The photodetector 110 may include a waveguide 114. The waveguide 114 may guide incoming light into the photodetector 110 for sensing by the sensor 100. The waveguide 114 may be arranged in and/or over the device layer 108. The waveguide 114 may include a semiconductor material having a bandgap narrower than the device layer 108 and the base substrate 104. In an embodiment of the disclosure, the waveguide 114 may include an indirect bandgap semiconductor material, such as germanium. The photodetector 110 may further include a first doped region 116 and a second doped region 118 at opposite sides of the waveguide 114. The second doped region 118 may be nearer to the temperature sensor 112 than the first doped region 116. The first doped region 116 and the second doped region 118 may be arranged substantially parallel to the waveguide 114, and may have a length extending along a significant length of the waveguide 114. The first doped region 116 and the second doped region 118 may include dopants having opposite conductivities, for example, n-type conductivity dopants and p-type conductivity dopants, respectively. Accordingly, the first doped region 116 may be commonly referred to as a cathode and the second doped region 118 may be commonly referred to as an anode. Examples of n-type conductivity dopants may include arsenic, phosphorus, or antimony, and examples of p-type conductivity dopants may include boron, aluminum, or gallium. Alternatively, the first doped region 116 may be an anode including dopants having p-type conductivity and the second doped region 118 may be a cathode including dopants having n-type conductivity.

The temperature sensor 112 may be a p-n junction diode, commonly referred to as a bandgap temperature sensor. The temperature sensor 112 may include a third doped region 120 and a fourth doped region 122 arranged substantially parallel to the waveguide 114, and each having a length extending along a significant length of the waveguide 114. In an embodiment of the disclosure, the third doped region 120 and the fourth doped region 122 may have similar lengths as the first doped region 116 and/or the second doped region 118. The third doped region 120 and the fourth doped region 122 may include dopants having opposite conductivities, for example, n-type conductivity dopants and p-type conductivity dopants, respectively. Accordingly, the third doped region 120 may be commonly referred to as a cathode and the fourth doped region 122 may be commonly referred to as an anode. Alternatively, the third doped region 120 may be an anode including dopants having p-type conductivity and the fourth doped region 122 may be a cathode including dopants having n-type conductivity.

The sensor 100 may further include a cavity 124 in the base substrate 104 of the substrate 102. A boundary of the cavity 124 in FIG. 1A is diagrammatically shown by a dashed line for purposes of illustration. The cavity 124 may be collectively surrounded by the buried insulator layer 106 from above and by the base substrate 104 of the substrate 102 from below and laterally, which fully seals the cavity 124. For example, a portion of the base substrate 104 enclosing the cavity 124 may define the longitudinal and transverse boundaries of the cavity 124, and a portion of the buried insulator layer 106 may form a substantially flat ceiling of the cavity 124.

The cavity 124 in the substrate 102 may define an air gap. The air gap may contain air at or near atmospheric pressure, or at sub-atmospheric pressure, for example, a partial vacuum. Although referred to as an “air gap”, the elemental composition of the air gap can include different gases and should not be construed as having any particular elemental composition, for example, any number and type of gases may be present in the air gap defined by the cavity 124. Additionally, the air gap defined by the cavity 124 may be characterized by a permittivity or a dielectric constant of near unity, for example, vacuum permittivity. The permittivity of the air gap may be less than the dielectric constant of the surrounding solid material, such as the buried insulator layer 106 and the base substrate 104 of the substrate 102.

The cavity 124 may be arranged vertically below the photodetector 110 and the temperature sensor 112. The cavity 124 may further extend beyond the boundary of the device layer 108 such that the photodetector 110 and the temperature sensor 112 are arranged within the boundary of the cavity 124. For example, the device layer 108 may include side surfaces 108_{S} extending downward from the upper substrate surface 102_{U} to the buried insulator layer 106, and the side surfaces 108_{S} may be arranged vertically over the cavity 124 and within the boundary thereof.

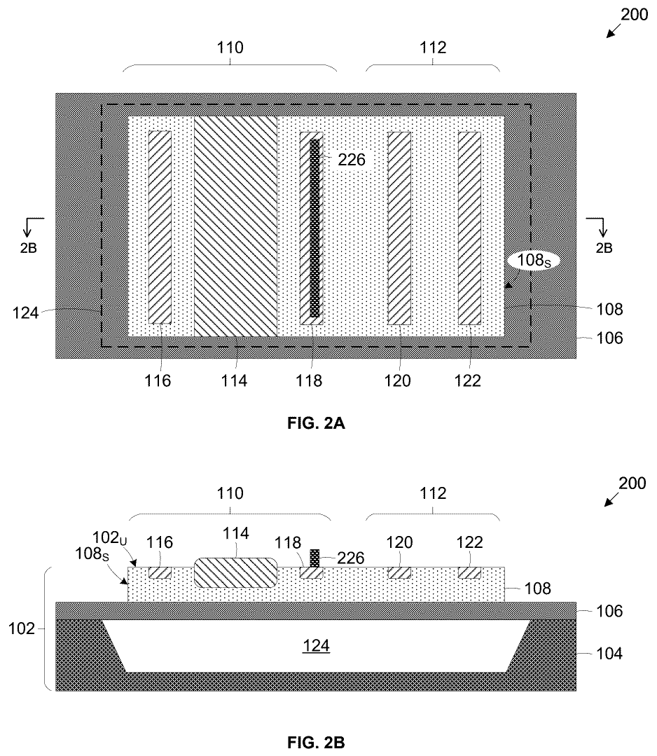

FIG. 2A is a top-down view of a sensor 200 and FIG. 2B is a cross-sectional view of the sensor 100 taken generally along line 2B-2B in FIG. 2A, according to an embodiment of the disclosure. The sensor 200 may be similar to the sensor 100, and thus common features are labeled with the same reference numerals and need not be separately discussed.

The sensor 200 may further include a via structure 226 coupled to the photodetector 110. The via structure 226 may serve to dissipate heat generated from the photodetector 110 to surrounding cooler areas. Functionally, the via structure 226 enables the heat generated from the photodetector 110 to spread out to provide a more uniform thermal profile at the temperature sensor 112. The via structure 226 may be electrically inactive, or electrically floating. For example, the via structure 226 may not be connected to a voltage source or a current source. The via structure 226 may include a thermally conductive metal, such as tungsten or copper.

The via structure 226 may be coupled to a doped region of the photodetector 110 that is closest to the temperature sensor 112, such as the second doped region 118. The via structure 226 may be arranged substantially parallel to and extending along a significant length of the second doped region 118. In an embodiment of the disclosure, the via structure 226 may be arranged proximately to a distal edge of the second doped region 118 from the waveguide 114, offset from a longitudinal plane of the second doped region 118. As used herein, “longitudinal plane” refers to a plane that runs through a center of and parallel to, or along, a length of a feature. In comparison, a transverse plane is a plane that is perpendicular to the longitudinal plane and the transverse plane runs across a length of a feature. In another embodiment of the disclosure, the via structure 226 may be arranged on the longitudinal plane of the second doped region 118. The via structure 226 may have a length shorter than the second doped region 118, as illustrated in FIG. 2A, or may have a length substantially equal to or longer than the second doped region 118.

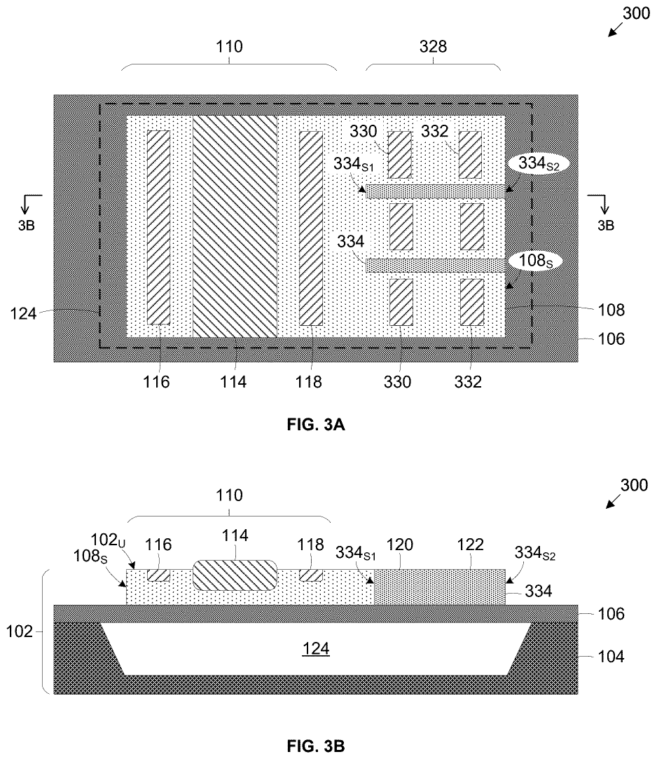

FIG. 3A is a top-down view of a sensor 300 and FIG. 3B is a cross-sectional view of the sensor 300 taken generally along line 3B-3B in FIG. 3A, according to an embodiment of the disclosure. The sensor 300 may be similar to the sensor 100, and thus common features are labeled with the same reference numerals and need not be separately discussed.

The sensor 300 may include more than one temperature sensor 328 laterally adjacent to the photodetector 110. For example, as illustrated, the sensor 300 may include three (3) temperature sensors 328 arranged along a significant length of the photodetector 110. In other embodiments of the disclosure, the sensor 300 may include two or more than three temperature sensors 328 adjacent to the photodetector 110. Each temperature sensor 328 may be similar to the temperature sensor 112 of the sensor 100 in FIGS. 1A and 1B. For example, each temperature sensor 328 of the sensor 300 may be a p-n junction diode. Each temperature sensor 328 may include a fifth doped region 330 and a sixth doped region 332 laterally spaced apart from the photodetector 110. The fifth doped region 330 and the sixth doped region 332 may be synonymous with the third doped region 120 and the fourth doped region 122, respectively, of the temperature sensor 112.

Each temperature sensor 328 may be separated from an adjacent temperature sensor 328 by an isolation structure 334 arranged in the device layer 108 of the substrate 102. The isolation structure 334 may be arranged vertically over and within the boundary of the cavity 124 in the substrate 102. The isolation structure 334 may extend downward from the upper substrate surface 102_{U} to a level in the device layer 108. In an embodiment of the disclosure, the isolation structure 334 may extend downward from the upper substrate surface 102_{U} to the buried insulator layer 106 of the substrate 102, as illustrated. In another embodiment of the disclosure (not shown), the isolation structure 334 may extend downward from the upper substrate surface 102_{U} to a depth at least as deep as the sixth doped region 332 and may not contact the buried insulator layer 106 such that a portion of the device layer 108 may be vertically between the isolation structure 334 and the buried insulator layer 106.

Each isolation structure 334 may include a side surface 334_{S1} proximate to the photodetector and a side surface 334_{S2} opposite to the side surface 334_{S1}. The side surfaces 334_{S1} and 334_{S2} may be substantially parallel to the waveguide 114 of the photodetector 110 and the side surface 334_{S2} may be coplanar with the side surface 108_{S} of the device layer 108, as illustrated in FIG. 3A. In another embodiment of the disclosure, the side surface 334_{S2} may be spaced inward from the side surface 108_{S} of the device layer such that a portion of the device layer 108 may be in contact with the side surface 334_{S2} of the isolation structure 334. The isolation structure 334 may be commonly referred to as a shallow trench isolation (STI) structure and may include an electrically insulating material, such as silicon dioxide. As illustrated in FIG. 3A, each isolation structure 334 may have a length perpendicular to the length of the waveguide 114.

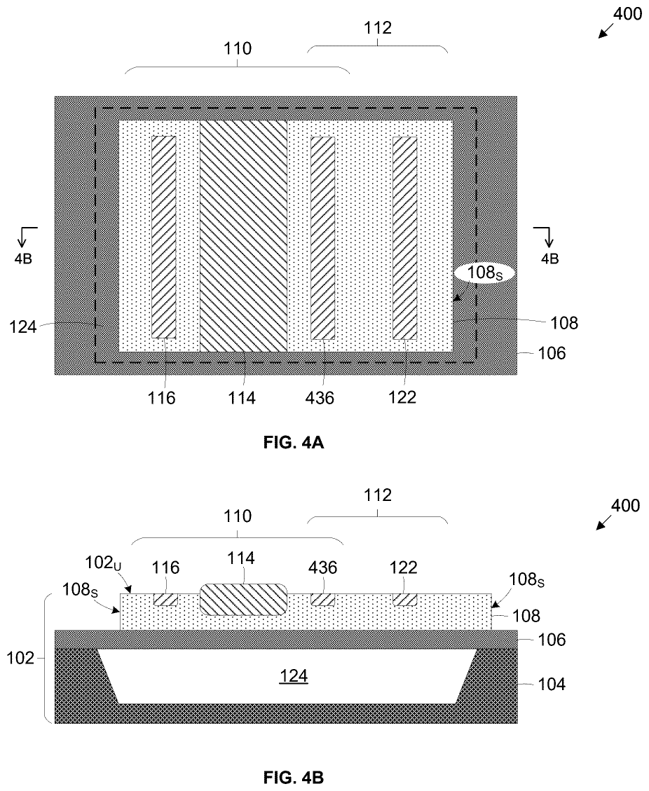

FIG. 4A is a top-down view of a sensor 400 and FIG. 4B is a cross-sectional view of the sensor 400 taken generally along line 4B-4B in FIG. 4A, according to an embodiment of the disclosure. The sensor 400 may be similar to the sensor 100, and thus common features are labeled with the same reference numerals and need not be separately discussed.

The sensor 400 may contain a shared or common doped region 436 between the photodetector 110 and the temperature sensor 112 to reduce the footprint of the sensor 400. The doped region 436 may be a common anode having p-type conductivity dopants or a common cathode having n-type conductivity dopants.

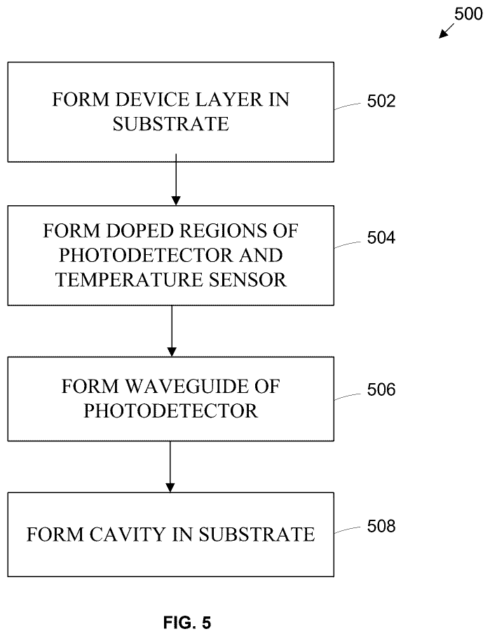

FIG. 5 is a flow chart illustrating an exemplary method of forming a sensor 500, according to an embodiment of the disclosure. The sensor 500 may be similar to the sensor 100 in FIGS. 1A and 1B. Certain structures may be fabricated, for example, using known processes and techniques, and specifically disclosed processes and methods may be used to achieve individual aspects of the present disclosure. The below-described order for the method of forming the magnetic memory device is intended to be illustrative, and the method is not limited to the specifically described order unless otherwise specifically stated.

As used herein, “deposition techniques” refer to the process of applying a material over another material. Exemplary techniques for deposition include, but not limited to, spin-on coating, sputtering, chemical vapor deposition (CVD), physical vapor deposition (PVD), molecular beam deposition (MBD), pulsed laser deposition (PLD), liquid source misted chemical deposition (LSMCD), or atomic layer deposition (ALD).

Additionally, “patterning techniques” include deposition of material or photoresist, patterning, exposure, development, etching, cleaning, and/or removal of the material or photoresist as required in forming a described pattern, structure, or opening. Exemplary examples of techniques for patterning include, but not limited to, wet etch photolithographic processes, dry etch photolithographic processes, or direct patterning processes.

A substrate may be provided. The substrate may be a composite semiconductor substrate, such as a semiconductor-on-insulator (SOI) substrate. The substrate may be synonymous with the substrate 102 in FIG. 1B. The substrate may include a base substrate, a buried insulator layer over the base substrate, and a semiconductor layer over the buried insulator layer. The base substrate and the buried insulator layer may be synonymous with the base substrate 104 and the buried insulator layer 106 in FIGS. 1A and 1B. The base substrate and the semiconductor layer may include a semiconductor material, such as silicon, germanium, silicon germanium, silicon carbide, or other II-VI or III-V semiconductor compounds, though not necessarily the same semiconductor material. The buried insulator layer may include an electrically insulating material, such as silicon dioxide or aluminum oxide.

A device layer may be formed in the substrate, as illustrated by operation 502. The device layer may be synonymous with the device layer 108 in FIGS. 1A and 1B. The device layer may be formed by patterning the semiconductor layer of the substrate using a patterning technique, including lithography and etching processes. A portion of the buried insulator layer may be exposed after the patterning technique. A portion of the device layer may be designated to form a photodetector therein and another laterally adjacent portion of the device layer may be designated to form a temperature sensor therein.

Doped regions may be formed in the device layer, as illustrated by operation 504. The doped regions may be synonymous with the first doped region 116, the second doped region 118, the third doped region 120, and the fourth doped region 122 in FIGS. 1A and 1B. The doped regions may be formed by a doping technique, including an ion implantation process, using ion species, for example, n-type or p-type conductivity dopants. The process conditions, for example, ion species, dose, and/or kinetic energy, may be selected to tune the electrical and physical characteristics of the doped regions. In an embodiment of the disclosure, two (2) doped regions having opposite dopant conductivities may be formed in the device region designated for a photodetector and two (2) doped regions having opposite dopant conductivities may be formed in the device region designated for a temperature sensor.

A waveguide may be formed in and/or over the device layer, as illustrated by operation 506. The waveguide may be synonymous with the waveguide 114 in FIGS. 1A and 1B. The waveguide may be formed by a deposition technique, including a CVD process or a molecular beam epitaxy (MBE) process, and a patterning technique, including lithography and etching processes. The waveguide may be part of the photodetector and may be formed between and substantially parallel to the doped regions in the device region designated for a photodetector. The waveguide may include a semiconductor material having a narrower bandgap than the device layer and the base substrate of the substrate. In an embodiment of the disclosure, the semiconductor waveguide is a germanium waveguide.

A cavity may be formed in the base substrate of the substrate, as illustrated by operation 508. The cavity may be synonymous with the cavity 124 in FIGS. 1A and 1B. Openings may be formed through the buried insulator layer of the substrate using a patterning technique, including lithography and etching processes. The openings may expose a portion of the base substrate of the substrate and define pilot holes through which the cavity may be formed in the base substrate of the substrate. The cavity in the base substrate of the substrate may be formed using a material removal technique, including an isotropic etching process such as, for example, a dry etching process using gases or a wet etching process using liquids.

Processing of the sensor 500 may continue with the formation of a heat spreader. The heat spreader may be synonymous with the via structure 226 in FIGS. 2A and 2B. The heat spreader may be formed by depositing a dielectric material over the sensor 500 using a deposition technique, including a CVD process. The dielectric material may be subsequently patterned using a patterning technique, including lithography and etching processes, to form an opening over a doped region of the photodetector. The opening may be filled with a thermally conductive material, such as a metal, including tungsten or copper, using a deposition technique, including a PVD process, a CVD process, or an electroplating process.

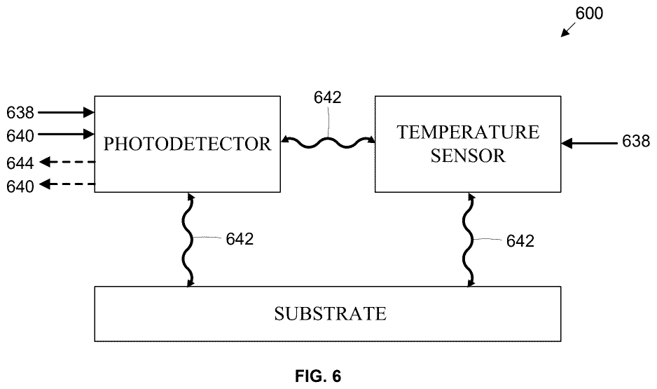

FIG. 6 is a diagram illustrating the flow of power in a sensor 600, according to an embodiment of the disclosure. The sensor 600 may be similar to the sensor 100 in FIGS. 1A and 1B. Power may take various forms, such as electrical power 638, optical power (light) 640, thermal power (heat) 642, or photoelectric power 642.

The sensor 600 may include a photodetector. The photodetector may be synonymous with the photodetector 110 in FIGS. 1A and 1B. Power may enter the photodetector in the form of electrical power 638, optical power 640, or coupled thermal power 642. Power may leave the photodetector in the form of photoelectric power 644, reflected or generated optical power 640, or thermal power 642 in the form of coupled heat or leakage heat. When a photodetector with indirect bandgap materials, such as a germanium waveguide, is operated in reverse bias, power lost in the form of photoelectric generated power 644 and reflected light may be assumed to be negligible.

The sensor 600 may further include a temperature sensor. The temperature sensor may be synonymous with the temperature sensor 112 in FIGS. 1A and 1B. Power may enter the temperature sensor in the form of coupled thermal power 642 or electrical power 638. Power may leave the temperature sensor in the form of thermal power 642 in the form of coupled heat or leakage heat. The electrical power 638 dissipated by the temperature sensor may be assumed to vary with temperature such that a reading of the temperature sensor depends primarily on the net power dissipated at the photodetector.

The sensor 600 may yet further include a substrate. The substrate may be synonymous with the base substrate 104 in FIG. 1B. Power may enter into the substrate by thermal power 642 in the form of leakage from the photodetector and/or from the temperature sensor.

As presented in the above disclosure, sensors including photodetectors with integrated temperature sensors and methods of forming the same are disclosed. The temperature sensor may be thermally coupled to the photodetector through the same slab of a device layer of a substrate. The temperature sensor may be used to thermally calibrate the photodetector by the Electrical Substitution Method (ESM). An exemplary calibration method is presented below.

The calibration of the photodetector requires obtaining a mapping of the amount of electrical power dissipated as heat from the photodetector in the absence of illumination and the corresponding readings of the temperature sensor. To achieve this, the photodetector may be used as a resistive heater, and a first measurement of current and voltage readings may be obtained by placing the photodetector in a forward bias condition. The amount of electrical power generated from the photodetector can be calculated by multiplying the current reading by the voltage reading. Concurrently, a first thermal reading from the temperature sensor may be measured. Multiple measurements of the photodetector may be performed with different forward bias conditions to obtain corresponding thermal readings from the temperature sensor, thereby generating the mapping of the electrical power dissipated as heat from the photodetector and the corresponding readings from the temperature sensor.

After the mapping has been generated, the photodetector may be placed in reverse bias conditions, and a source optical power can be set. A second measurement of current and voltage readings may be obtained from the photodetector, and the corresponding electrical power, generated or dissipated, can be calculated from these readings. A second thermal reading from the temperature sensor may be measured. Using the generated mapping, the corresponding amount of power dissipated as heat from both electrical and optical sources at the photodetector can be obtained. Finally, the incident optical power can be calculated by subtracting the electrical power dissipated as heat 604 from the total power dissipated as heat.

The terms “top”, “bottom”, “over”, “under”, and the like in the description and the claims, if any, are used for descriptive purposes and not necessarily for describing permanent relative positions. It is to be understood that the terms so used are interchangeable under appropriate circumstances such that the embodiments of the devices described herein are, for example, capable of operation in other orientations than those illustrated or otherwise described herein.

Additionally, the formation of a first feature over or on a second feature in the description that follows may include embodiments in which the first and second features are formed in direct contact, and may also include embodiments in which additional features may be formed by interposing the first and second features, such that the first and second features may not be in direct contact.

Similarly, if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of features is not necessarily limited to those features but may include other features not expressly listed or inherent to such process, method, article, or device. Occurrences of the phrase “in an embodiment” herein do not necessarily all refer to the same embodiment.

In addition, unless otherwise indicated, all numbers expressing quantities, ratios, and numerical properties of materials, reaction conditions, and so forth used in the specification and claims are to be understood as being modified in all instances by the term “about”.

Furthermore, approximating language, as used herein throughout the specification and claims, may be applied to modify any quantitative representation that could permissibly vary without resulting in a change in the basic function to which it is related. Accordingly, a value modified by a term or terms, such as “approximately”, “about,” or “substantially” is not limited to the precise value specified. In some instances, the approximating language may correspond to the precision of an instrument for measuring the value. In other instances, the approximating language may correspond to within normal tolerances of the semiconductor industry. For example, “substantially coplanar” means substantially in a same plane within normal tolerances of the semiconductor industry, and “substantially perpendicular” means at an angle of 90 degrees plus or minus a normal tolerance of the semiconductor industry.

While several exemplary embodiments have been presented in the above-detailed description of the device, it should be appreciated that a number of variations exist. It should further be appreciated that the embodiments are only examples, and are not intended to limit the scope, applicability, dimensions, or configuration of the device in any way. Rather, the above-detailed description will provide those skilled in the art with a convenient road map for implementing an exemplary embodiment of the device, it is understood that various changes may be made in the function and arrangement of features and methods of fabrication described in an exemplary embodiment without departing from the scope of this disclosure as set forth in the appended claims.

What is claimed is:

1. A sensor for sensing illumination, comprising:
a substrate including a device layer over a substrate;
a photodetector in the device layer; and
a temperature sensor in the device layer adjacent to the photodetector.

2. The sensor of claim 1, wherein the photodetector is immediately adjacent to the temperature sensor, and intervening structures are absent in the device layer between the photodetector and the temperature sensor.

3. The sensor of claim 1, wherein the substrate comprises a base substrate under the device layer and further comprising a cavity in the base substrate vertically below the device layer, wherein the temperature sensor and the photodetector are within a boundary of the cavity.

4. The sensor of claim 2, wherein the photodetector further comprises:
a first doped region in the device layer;
a second doped region in the device layer spaced apart from the first doped region; and
a waveguide between the first doped region and the second doped region.

5. The sensor of claim 4, wherein the device layer and the waveguide each comprise a semiconductor material, and the semiconductor material of the waveguide has a narrower bandgap than the semiconductor material of the device layer.

6. The sensor of claim 5, wherein the semiconductor material of the waveguide is germanium.

7. The sensor of claim 4, wherein the first doped region and the second doped region are substantially parallel to the waveguide and have a length extending along a significant length of the waveguide.

8. The sensor of claim 4, further comprising an electrically inactive via structure on the second doped region of the photodetector.

9. The sensor of claim 8, wherein the via structure is substantially parallel to the second doped region and has a length extending along a significant length of the second doped region.

10. The sensor of claim 9, wherein the via structure is at an offset from a longitudinal plane of the second doped region.

11. The sensor of claim 10, wherein the via structure is arranged proximate to a distal edge of the second doped region from the waveguide.

12. The sensor of claim 4, wherein the temperature sensor further comprises:
a third doped region in the device layer; and
a fourth doped region in the device layer spaced apart from the third doped region, wherein the third doped region and the fourth doped region are substantially parallel to the waveguide and have a length extending along a significant length of the waveguide.

13. The sensor of claim 4, wherein the temperature sensor further comprises a third doped region including dopants having an opposite conductivity to the second doped region, and the second doped region is a shared doped region for the photodetector and the temperature sensor.

14. The sensor of claim 4, wherein the temperature sensor in the device layer is one of a plurality of temperature sensors in the device layer adjacent to the photodetector.

15. The sensor of claim 14, wherein the plurality of temperature sensors is arranged along a significant length of the photodetector.

16. The sensor of claim 15, wherein each temperature sensor of the plurality of temperature sensors is spaced apart from an adjacent temperature sensor by an isolation structure in the device layer of the substrate.

17. The sensor of claim 16, wherein the substrate further comprises a buried insulator layer between the device layer and a base substrate, and the isolation structure extends from the device layer to the buried insulator layer.

18. The sensor of claim 17, wherein the isolation structure comprises side surfaces, and one of the side surfaces is coplanar with a side surface of the device layer.

19. A method of forming a sensor for sensing illumination, comprising:
forming a photodetector in a device layer of a substrate, the substrate comprising a base substrate under the device layer; and
forming a temperature sensor in the device layer adjacent to the photodetector.

20. The method of claim 19, further comprising forming a cavity in the base substrate vertically below the device layer, wherein the temperature sensor and the photodetector are within a boundary of the cavity.
